(19) United States
(12) Patent Application Publication
(10) Pub. No.: US 2026/0095180 A1
(43) Pub. Date: Apr. 2, 2026

(54) SWITCH DEVICE

(71) Applicant: Panasonic Automotive Systems Co., Ltd., Kanagawa (JP)

(72) Inventors: Yuhei CHIDA, Osaka (JP); Takeshi MIYAOKA, Osaka (JP); Masahiro JIGI, Fukui (JP); Takuma FUJII, Osaka (JP)

(73) Assignee: Panasonic Automotive Systems Co., Ltd., Kanagawa (JP)

(21) Appl. No.: 19/277,906

(22) Filed: Jul. 23, 2025

(30) Foreign Application Priority Data
Sep. 30, 2024 (JP) 2024-170904

(51) Int. Cl. H03K 17/96

(52) U.S. Cl. CPC H03K 17/962; H03K 2217/94036; H03K 2217/96015; H03K 2217/96054

(57) ABSTRACT

A switch device is a switch device provided in a vehicle. The switch device includes: a panel that receives a user operation; a cover that displaces between an open position in which the panel is exposed and a closed position in which the panel is covered; a capacitive sensor electrode provided on an opposite side of the panel relative to a cover side of the panel; a cover state detector that detects a state of the cover indicating the open position or the closed position; and a controller that determines, based on an operation signal output by the capacitive sensor electrode, whether an operation has been performed on the switch device. The controller changes detection sensitivity of the capacitive sensor electrode depending on the state of the cover detected by the cover state detector.

### CROSS REFERENCE TO RELATED APPLICATION

The present application is based on and claims priority of Japanese Patent Application No. 2024-170904 filed on Sep. 30, 2024.

### FIELD

The present disclosure relates to a switch device.

### BACKGROUND

In recent years, users operate operation buttons and the like provided inside passenger cabins to control in-vehicle equipment items to perform functions of the in-vehicle equipment items provided in vehicles.

For example, the switch device according to Patent Literature (PTL) 1 includes: an electrode, a detection means for detecting whether or not an operation has been performed by a change in capacitance of the electrode, a cover portion that is approximately board-shaped, includes a non-conductive material, and is provided to be openable and closable on a surface on which the electrode is operated, and a switching means for switching functions according to a detection result of the detection means. The switching means determines whether an operation has been performed on the electrode when the cover portion is opened or closed, and switches between functions corresponding to respective operations.

### CITATION LIST

### Patent Literature

PTL 1: Japanese Unexamined Patent Application Publication No. 2010-129329

### SUMMARY

However, the switch device according to the above PTL 1 can be improved upon.

In view of this, the present disclosure provides a switch device capable of improving upon the above related art.

A switch device according to one aspect of the present disclosure is a switch device provided in a vehicle. The switch device includes: a panel that receives a user operation; a cover that displaces between an open position in which the panel is exposed and a closed position in which the panel is covered; a capacitive sensor electrode provided on an opposite side of the panel relative to a cover side of the panel; a cover state detector that detects a state of the cover indicating the open position or the closed position; and a controller that determines, based on an operation signal output by the capacitive sensor electrode, whether an operation has been performed on the switch device. The controller changes detection sensitivity of the capacitive sensor electrode depending on the state of the cover detected by the cover state detector.

A switch device according to one aspect of the present disclosure is capable of improving upon the above related art.

### BRIEF DESCRIPTION OF DRAWINGS

These and other advantages and features of the present disclosure will become apparent from the following description thereof taken in conjunction with the accompanying drawings that illustrate a specific embodiment of the present disclosure.

FIG. 1 is a diagram schematically illustrating a switch device according to an embodiment which is provided in a vehicle.

FIG. 2 is a block diagram illustrating the switch device according to the embodiment.

FIG. 3 is a side view of the switching device according to the embodiment when a cover is in a closed position.

FIG. 4 is a side view of the switching device according to the embodiment when the cover is in an open position.

FIG. 5 is a flowchart illustrating the switch device according to the embodiment.

FIG. 6 is another flowchart illustrating the switch device according to the embodiment.

### DESCRIPTION OF EMBODIMENT

Hereinafter, embodiments will be described in detail with reference to the drawings.

Note that the embodiments below each describe a general or specific example. The numerical values, shapes, materials, elements, the arrangement and connection of the elements, steps, orders of the steps, etc., presented in the embodiment below are mere examples, and are not intended to limit the present disclosure. Furthermore, among the elements in the embodiments below, those not recited in any one of the independent claims will be described as optional elements.

In addition, the drawings are schematic diagrams, and do not necessarily provide strictly accurate illustrations. Throughout the drawings, the same reference numeral is given to the same element.

In the following embodiment, expressions such as quadrilateral in shape, approximately parallel, etc., are used. For instance, quadrilateral in shape and approximately parallel not only mean perfectly quadrilateral and perfectly parallel, but also mean substantially quadrilateral and substantially parallel. In other words, these expressions mean to include an error of about several percent. Moreover, quadrilateral in shape and approximately parallel mean quadrilateral and approximately parallel to the extent that the advantageous effects of the present disclosure can be achieved. The same applies to other expressions using “shape” and “approximately”.

### EMBODIMENT

### [Configuration]

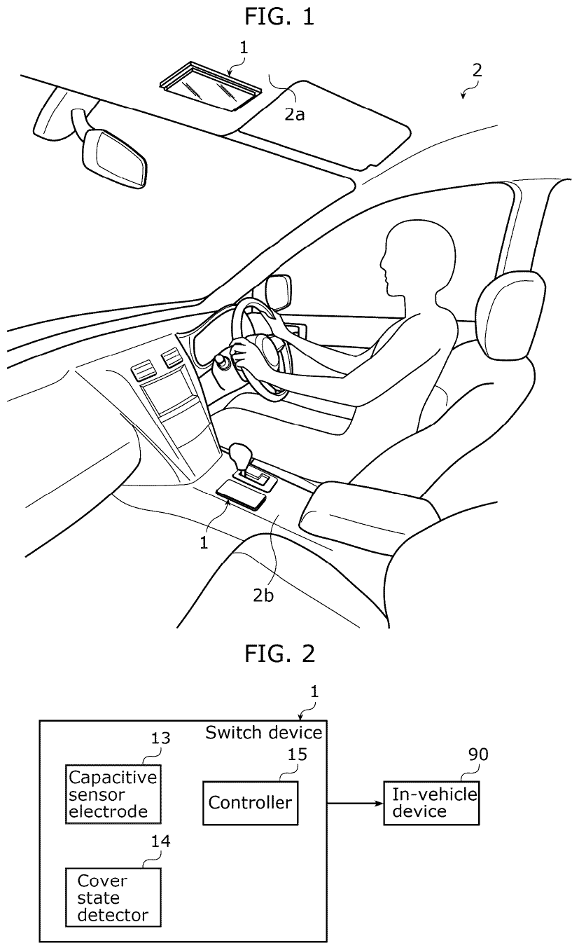

First, switch device 1 included in vehicle 2 will be described with reference to FIG. 1 through FIG. 4.

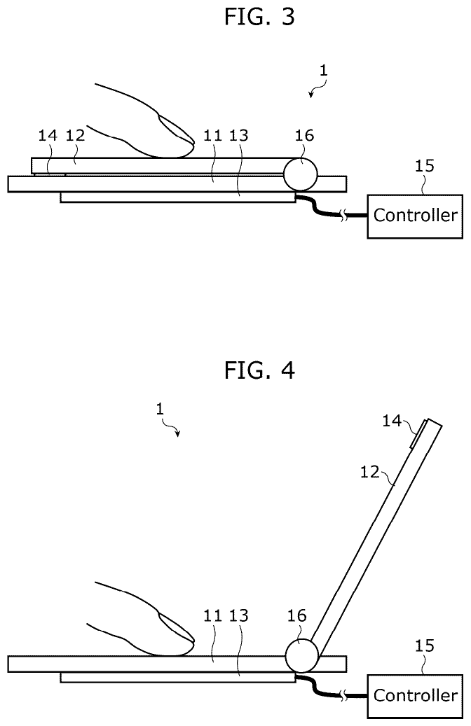

FIG. 1 is a diagram schematically illustrating switch device 1 according to an embodiment which is provided in vehicle 2. FIG. 2 is a block diagram illustrating switch device 1 according to the embodiment. FIG. 3 is a side view of switching device 1 according to the embodiment when cover 12 is in a closed position. FIG. 4 is a side view of switching device 1 according to the embodiment when cover 12 is in an open position.

As illustrated in FIG. 1, vehicle 2 is provided with switch devices 1. Each of switch devices 1 is used as an operation input device to be provided in vehicle 2. Specifically, switch devices 1 are provided in a steering wheel, a center cluster, a door panel, an instrument panel, etc., which are provided in vehicle 2. FIG. 1 of the present embodiment shows an example in which switch devices 1 are provided in overhead console 2a and center console 2b.

Switch devices 1 can operate in-vehicle devices 90 provided in vehicle 2 by receiving operation inputs from a user using operation items. The operation items include a human finger, a stylus, etc. In-vehicle devices 90 include an air conditioner, a lighting device, an acoustic device, an in-vehicle display, a navigation system, power windows, a sunroof motor, etc.

As illustrated in FIG. 2 through FIG. 4, switch device 1 includes panel 11, cover 12, capacitive sensor electrode 13, cover state detector 14, and controller 15.

Panel 11 is an operation board for receiving a user operation. Panel 11 includes a resin material, etc., and is in the shape of a flat, quadrilateral board. Note that the shape of panel 11 is not limited to a quadrilateral shape, and may be in the shape of, for example, a circle or a polygon other than a quadrilateral.

Cover 12 includes a resin material, etc., and is in the shape of a flat, quadrilateral board. Note that the shape of cover 12 is not limited to a quadrilateral shape, and may be in the shape of, for example, a circle or a polygon other than a quadrilateral.

Cover 12 has one edge that is pivotably coupled to panel 11. Specifically, cover 12 is coupled to panel 11 by hinge 16. For this reason, cover 12 can displace between an open position in which panel 11 is exposed and a closed position in which panel 11 is covered.

As illustrated in FIG. 3, when cover 12 is in the closed position, cover 12 covers an upper surface of panel 11 and overlaps panel 11 so as to be in an orientation approximately parallel to panel 11. The upper surface of panel 11 is a surface that faces cover 12 when cover 12 is in the closed position.

As illustrated in FIG. 4, when cover 12 is in the open position, cover 12 pivots relative to panel 11 so as to avoid overlapping panel 11 and to expose the upper surface of panel 11.

Capacitive sensor electrode 13 is an electrode provided on the opposite side (back surface side) of panel 11 relative to the cover 12 side (upper surface side) of panel 11. Capacitive sensor electrode 13 can detect (i) an operation performed on panel 11 when cover 12 is in the open position and (ii) an operation performed on cover 12 when cover 12 is in the closed position. Capacitive sensor electrode 13 outputs, to controller 15, an operation signal obtained by detecting an operation regardless of whether cover 12 is in the open position or in the closed position.

Cover state detector 14 is a sensor that detects a state of cover 12 indicating the open position and closed position. Cover state detector 14 includes, for example, an optical sensor, infrared sensor, magnetometric sensor, or pressure sensor provided on cover 12 or panel 11. In the present embodiment, cover state detector 14 is provided on an end portion of cover 12 on the opposite side relative to an end portion on the hinge 16 side of cover 12.

When S11 detector 14 detects that cover 12 has been brought into the open position, cover state detector 14 may output, to controller 15, a signal indicating the open position. Moreover, when cover state detector 14 detects that cover 12 has been brought into the closed position, cover state detector 14 may output, to controller 15, a signal indicating the closed position.

Controller 15 can determine whether an operation has been performed on switch device 1 based on an operation signal output by capacitive sensor electrode 13. For example, controller 15 can determine that an operation has been performed on switch device 1 when an output value (voltage) of an operation signal output by capacitive sensor electrode 13 is greater than or equal to a predetermined value. Alternatively, controller 15 can determine that no operation has been performed on switch device 1 when an output value (voltage) of the operation signal is less than the predetermined value.

In addition, controller 15 can change the detection sensitivity of capacitive sensor electrode 13 depending on the state of cover 12 detected by cover state detector 14.

Specifically, controller 15 can set the detection sensitivity of capacitive sensor electrode 13 higher when cover 12 is in the closed position than when cover 12 is in the open position. For example, when controller 15 obtains, from cover state detector 14, a signal indicating that cover 12 is in the open position, controller 15 can set the detection sensitivity of capacitive sensor electrode 13 to first sensitivity. The first sensitivity is sensitivity capable of detecting at least an operation performed when cover 12 is in the open position. Moreover, when controller 15 obtains, from cover state detector 14, a signal indicating that cover 12 is in the closed position, controller 15 can set the detection sensitivity of capacitive sensor electrode 13 to second sensitivity that is higher in sensitivity than the sensitivity of the first sensitivity. The second sensitivity is sensitivity capable of detecting at least an operation performed when cover 12 is in the closed position. A distance from capacitive sensor electrode 13 to the upper surface of cover 12 when cover 12 is in the closed position is greater than a distance from capacitive sensor electrode 13 to the upper surface of panel 11 when cover 12 is in the open position. For this reason, the detection sensitivity of capacitive sensor electrode 13 is set higher when cover 12 is in the closed position than when cover 12 is in the open position, to facilitate, as well, the detection of an operation performed on the upper surface of cover 12 when cover 12 is in the closed position.

Controller 15 may be configured to perform different functions depending on when an operation is determined to have been performed when cover 12 is in the open position and when an operation is determined to have been performed when cover 12 is in the closed position. For example, an operation performed when cover 12 is in the open position may correspond to a function of closing the sunroof by outputting a signal to a sunroof motor to actuate the sunroof motor, and an operation performed when cover 12 is in the closed position may correspond to a function of opening the sunroof by outputting a signal to the sunroof motor to actuate the sunroof motor. With this, a single switch device 1 can serve a plurality of functions.

As described above, controller 15 can switch between (i) a function to be performed in response to receiving an operation performed on panel 11 when the state of cover 12 is detected to indicate the open position and (ii) a function to be performed in response to receiving an operation performed on cover 12 when the state of cover 12 is detected to indicate the closed position.

It should be noted that the functions are not limited to opening and closing the sunroof. The functions correspond to respective functions that in-vehicle devices 90 have. For example, functions of an air conditioner may correspond to a function of starting the air conditioner and a function of stopping the air conditioner, a function of increasing the air volume and a function of decreasing the air volume, or a function of increasing the temperature and a function of decreasing the temperature. Functions of a lighting device may correspond to a function of turning ON the light and a function of turning OFF the light, or a function of increasing the illuminance and a function of decreasing the illuminance. Functions of an acoustic device may correspond to a function of outputting sounds and a function of stopping sounds, or a function of turning up the volume and a function of turning down the volume. Functions of an in-vehicle display may correspond to a function of displaying a desired image and a function of displaying a default image. Function of a navigation system may correspond to a function of starting navigation and a function of stopping the navigation. Functions of power windows may correspond to a function of closing a window and a function of opening a window. It should be noted that switch device 1 may perform other widely-known functions performed by in-vehicle devices 90.

The above example has presented, for example, a single switch device 1 that is configured to be capable of serving a plurality of functions so as to be capable of detecting an operation performed when cover 12 is in the open position and an operation performed when cover 12 is in the closed position. However, switch device 1 may be configured to serve a single function so as to be capable of detecting only an operation performed when cover 12 is in the open position, for example.

More specifically, controller 15 can set the detection sensitivity of capacitive sensor electrode 13 higher when cover 12 is in the open position than when cover 12 is in the closed position. For example, when controller 15 obtains, from cover state detector 14, a signal indicating that cover 12 is in the open position, controller 15 can set the detection sensitivity of capacitive sensor electrode 13 to third sensitivity. The third sensitivity is sensitivity capable of detecting at least an operation performed when cover 12 is in the open position, and may be the same sensitivity as the first sensitivity, for example. Moreover, when controller 15 obtains, from cover state detector 14, a signal indicating that cover 12 is in the closed position, controller 15 can set the detection sensitivity of capacitive sensor electrode 13 to fourth sensitivity that is lower in sensitivity than the third sensitivity. The fourth sensitivity is sensitivity not detecting an operation performed when cover 12 is in the closed position. As described above, it is considered that, due to the thickness of cover 12, the detection sensitivity of capacitive sensor electrode 13 when cover 12 is in the closed position is lower than the detection sensitivity of capacitive sensor electrode 13 when the cover 12 is in the open position. However, when switch device 1 is used as a device that serves a single function, contact with switch device 1 is detected when cover 12 is in the open position to avoid capacitive sensor electrode 13 detecting only mere contact with cover 12 as an operation when cover 12 is in the closed position. Moreover, when controller 15 detects that the state of cover 12 has switched to the open position, controller 15 can also set the detection sensitivity of capacitive sensor electrode 13 higher for a predetermined time period than the detection sensitivity after a lapse of the predetermined time period. When cover 12 is shifted to the open position, this is thought to be an action taken to open cover 12 to perform an operation. Accordingly, in order to make certain of detecting that an operation has been performed, controller 15 may set, for a predetermined time period, the detection sensitivity of capacitive sensor electrode 13 to fifth sensitivity that is higher than reference sensitivity (first sensitivity) set when cover 12 is in the open position, upon obtaining a signal indicating that cover 12 is in the open position from cover state detector 14. The fifth sensitivity may be, for example, higher than the reference sensitivity (first sensitivity) and lower than the second sensitivity. After a lapse of the predetermined time period, the detection sensitivity can be restored to the reference sensitivity (first sensitivity) that is the detection sensitivity set when cover 12 is brought into the open position.

With this, when cover 12 is opened for an operation, performance of the operation is even more certainly detected.

In addition, in response to receiving a particular operation performed on cover 12 when cover 12 is in the closed position, controller 15 can also switch to a function corresponding to the particular operation. Particular operations are different from a normal operation. The particular operations are preset operations, and are, for example, a press-and-hold operation performed on switch device 1 and a double-tap operation performed on switch device 1. The normal operation is, for example, a single-tap operation performed on switch operation 1. Functions may be associated with respective particular operations.

Moreover, even if the same particular operation is performed when cover 12 is in the closed position and open position, controller 15 may cause respective in-vehicle devices 90 to carry out different functions.

### Operation Example 1

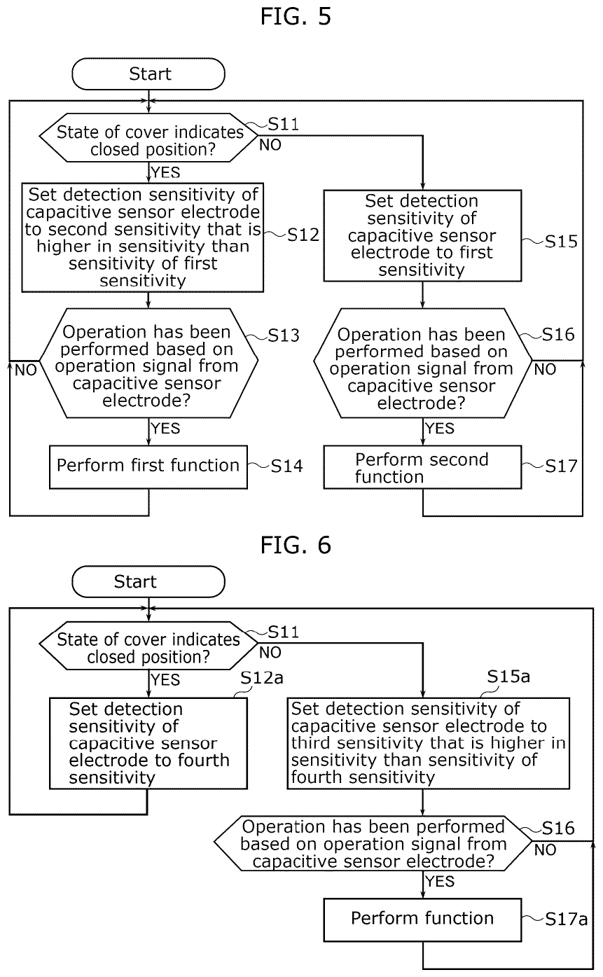

First, operation example 1 of switch device 1 will be described with reference to FIG. 5.

FIG. 5 is a flowchart illustrating switch device 1 according to the embodiment. FIG. 5 illustrates the case where the detection sensitivity is set higher when cover 12 is in the closed position than when cover 12 is in the open position.

First, controller 15 determines the state of cover 12 based on a signal obtained from cover state detector 14. Specifically, controller 15 determines whether the state of cover 12 indicates the closed position (S11). When cover state detector 14 detects that the state of cover 12 indicates the open position, cover state detector 14 outputs a signal indicating the open position to controller 15. Alternatively, when cover state detector 14 detects that the state of cover 12 indicates the closed position, cover state detector 14 outputs a signal indicating the closed position to controller 15.

Next, when controller 15 obtains the signal indicating the closed position from cover state detector 14, controller 15 determines that the state of cover 12 indicates the closed position (Yes in S11), and sets the detection sensitivity of capacitive sensor electrode 13 to the second sensitivity that is higher in sensitivity than the sensitivity of the first sensitivity (S12). Moreover, controller 15 makes a transition to a standby state for obtaining an operation signal from capacitive sensor electrode 13.

Next, controller 15 determines, based on an operation signal from capacitive sensor electrode 13, whether an operation has been performed (S13).

When controller 15 determines, based on the operation signal from capacitive sensor electrode 13, that no operation has been performed (No in S13), controller 15 goes back to perform the process from step S11. Note that the process of S13 may be performed again when No is received as the answer to step S13.

Meanwhile, when controller 15 determines, based on the operation signal from capacitive sensor electrode 13, that an operation has been performed (Yes in S13), controller 15 performs a first function for operating in-vehicle device 90 (S14). For example, when in-vehicle device 90 is a sunroof motor, the first function is a function of closing the sunroof by actuating the sunroof motor. The first function indicates a function that in-vehicle device 90 has.

Thereafter, controller 15 goes back to perform the process from step S11.

The process goes back to the determination in step S11. When controller 15 obtains, from cover state detector 14, a signal indicating that cover 12 is in the open position, controller 15 determines the state of cover 12 indicates the open position (No in S11), and sets the detection sensitivity of capacitive sensor electrode 13 to the first sensitivity (S15). Moreover, controller 15 makes a transition to a standby state for obtaining an operation signal from capacitive sensor electrode 13.

Next, controller 15 determines, based on an operation signal from capacitive sensor electrode 13, whether an operation has been performed (S16).

When controller 15 determines that no operation has been performed based on the operation signal from capacitive sensor electrode 13 (No in S16), controller 15 goes back to perform the process from step S11. Note that the process of S16 may be performed again when No is received as the answer to step S16.

Meanwhile, when controller 15 determines, based on the operation signal from capacitive sensor electrode 13, that an operation has been performed (Yes in S16), controller 15 performs a second function for operating in-vehicle device 90 (S17). For example, when in-vehicle device 90 is a sunroof motor, the second function is a function different from the first function, and is a function of opening the sunroof by actuating the sunroof motor. The second function indicates a function that in-vehicle device 90 has.

Thereafter, controller 15 goes back to perform the process from step S11.

### Operation Example 2

Operation example 2 of switch device 1 will be described with reference to FIG. 6.

FIG. 6 is another flowchart illustrating switch device 1 according to the embodiment. FIG. 6 illustrates the case where the detection sensitivity is set higher when cover 12 is in the open position than when cover 12 is in the closed position. Note that in the present operation example, the same reference numerals are given to operations the same as those in operation example 1 and description is appropriately omitted.

First, controller 15 determines whether the state of cover 12 indicates the closed position (S11).

Next, when controller 15 obtains a signal indicating the closed position from cover state detector 14, controller 15 determines that the state of cover 12 indicates the closed position (Yes in S11), and sets the detection sensitivity of capacitive sensor electrode 13 to the fourth sensitivity (S12a).

The fourth sensitivity when cover 12 is in the closed position includes the case where the detection sensitivity is 0 (no detection state). It should be noted that controller 15 does not obtain an operation signal from capacitive sensor electrode 13. Moreover, even if such an operation signal is obtained, controller 15 may abandon the operation signal.

When controller 15 does not obtain an operation signal from capacitive sensor electrode 13, controller 15 goes back to perform the process from step S11.

The process goes back to the determination in step S11. When controller 15 obtains, from cover state detector 14, a signal indicating that cover 12 is in the open position, controller 15 determines the state of cover 12 indicates the open position (No in S11), and sets the detection sensitivity of capacitive sensor electrode 13 to the third sensitivity that is higher in sensitivity than the sensitivity of the fourth sensitivity (S15a). Moreover, controller 15 makes a transition to a standby state for obtaining an operation signal from capacitive sensor electrode 13.

Next, controller 15 determines, based on an operation signal from capacitive sensor electrode 13, whether an operation has been performed (S16).

When controller 15 determines, based on the operation signal from capacitive sensor electrode 13, that no operation has been performed (No in S16), controller 15 goes back to perform the process from step S11.

Meanwhile, when controller 15 determines, based on the operation signal from capacitive sensor electrode 13, that an operation has been performed (Yes in S16), controller 15 performs a function for operating in-vehicle device 90 (S17a). This function serves as, for example, switch device 1 for emergency.

Thereafter, controller 15 goes back to perform the process from step S11.

### Advantageous Effects

Next, advantageous effects produced by switch device 1 according to the present embodiment will be described.

For example, the switch device according to PTL 1 can further be improved so as to even more certainly detect that an operation has been performed on the switch device including a cover portion.

In view of the above, as has been described, switch device 1 according to technical aspect 1 of the present embodiment is switch device 1 provided in vehicle 2. Switch device 1 includes: panel 11 that receives a user operation; cover 12 that displaces between an open position in which panel 11 is exposed and a closed position in which panel 11 is covered; capacitive sensor electrode 13 provided on the opposite side of panel 11 relative to the cover 12 side of panel 11; cover state detector 14 that detects a state of cover 12 indicating the open position or the closed position; and controller 15 that determines, based on an operation signal output the capacitive sensor electrode 13, whether an operation has been performed on switch device 1. Controller 15 changes detection sensitivity of capacitive sensor electrode 13 depending on the state of cover 12 detected by cover state detector 14.

According to the above, capacitive sensor electrode 13 when cover 12 is in the open position can have detection sensitivity different from the detection sensitivity of capacitive sensor electrode 13 when cover 12 is in the closed position. For this reason, capacitive sensor electrode 13 can detect an operation performed on switch device 1 regardless of the state of cover 12.

Therefore, the above-described switch device 1 can even more certainly detect that an operation has been performed.

Switch device 1 according to technical aspect 2 of the present embodiment is switch device 1 according to technical aspect 1. In this case, controller 15 sets the detection sensitivity of capacitive sensor electrode 13 higher when cover 12 is in the closed position than when cover 12 is in the open position.

The thickness from capacitive sensor electrode 13 to the upper surface of cover 12 is greater when cover 12 is in the closed position than when cover 12 is in the open position. Despite the fact above, an operation performed on the upper surface of cover 12 is readily detected by setting the detection sensitivity of capacitive sensor electrode 13 high. Therefore, an operation performed on cover 12 can be more certainly detected than the related art can.

In particular, since whether cover 12 is in the open position or in the closed position can be detected, switch device 1 can be configured to carry out different functions depending on the case where cover 12 is in the open position and the case where cover 12 is in the closed position when a user performs an operation on switch device 1. In other words, a single switch device 1 can serve multiple functions.

Moreover, switch device 1 according to technical aspect 3 of the present embodiment is switch device 1 according to technical aspect 1 or 2. In this case, controller 15 switches between (i) a function to be performed in response to receiving an operation performed on panel 11 when the state of cover 12 is detected to indicate the open position and (ii) a function to be performed in response to receiving an operation performed on cover 12 when the state of cover 12 is detected to indicate the closed position.

According to the above, different functions can be performed when an operation is performed on cover 12 depending on the case where cover 12 is in the open position and the case where cover 12 is in the closed position. Therefore, functions can be appropriately switched depending on the state of cover 12. For this reason, a single switch device 1 can serve multiple functions.

In addition, switch device 1 according to technical aspect 4 of the present embodiment is switch device 1 according to any one of technical aspects 1 to 3. In this case, controller 15 switches to a function corresponding to a particular operation in response to receiving the particular operation performed on cover 12 when cover 12 is in the closed position.

According to the above, operations to be received can be different depending on the case where cover 12 is in the closed position and the case where cover 12 is in the open position. For this reason, switch device 1 can be configured to carry out different functions depending on the case where cover 12 is in the open position and the case where cover 12 is in the closed position when a user performs an operation on switch device 1. Accordingly, the above-described switch device 1 can be configured to have a plurality of functions.

Moreover, switch device 1 according to technical aspect 5 of the present embodiment is switch device 1 according to technical aspect 1. In this case, controller 15 sets the detection sensitivity of capacitive sensor electrode 13 higher when cover 12 is in the open position than when cover 12 is in the closed position.

According to the above, switch device 1 can be configured as, for example, a switch device that serves a single function such that the switch device can detect only an operation performed when cover 12 is in the open position.

In addition, switch device 1 according to technical aspect 6 of the present embodiment is switch device 1 according to technical aspect 1. In this case, when controller 15 detects that the state of cover 12 has switched to the open position, controller 15 sets the detection sensitivity of capacitive sensor electrode 13 higher for a predetermined time period than the detection sensitivity of capacitive sensor electrode 13 after a lapse of the predetermined time period.

According to the above, setting the sensitivity high for a predetermined time period upon obtaining a signal indicating that cover 12 is in the open position allows detection of performance of an operation to be even more certain when the operation is performed with cover 12 opened.

### [Other Variations]

Hereinbefore, the switch device according to the present disclosure has been described based on the above-described embodiment, but the present disclosure is not limited to the embodiment. The present disclosure may encompass embodiments arrived at by a person of skill in the art making various modifications to the embodiment as long as the embodiments do not depart from the spirit of the present disclosure.

For example, the controller, etc., included in the switch device according to the above-described embodiment are typically implemented by large-scale integration (LSI) circuits that are integrated circuits. These elements may be individually implemented as a single chip, or some or all of the elements may be implemented as a single chip.

Circuit integration is not limited to LSI; the elements may be implemented as a dedicated circuit or generic processor. A field programmable gate array (FPGA) that is programmable after manufacturing of the LSI circuit, or a reconfigurable processor whose circuit cell connections and settings in the LSI circuit are reconfigurable, may be used.

Note that, in the above embodiments, the elements may be configured as dedicated hardware product or may be implemented by executing a software program suitable for the element. Each element may be implemented as a result of a program execution unit, such as the central processing unit (CPU) or processor or the like, loading and executing a software program stored in a storage medium such as a hard disk or semiconductor memory.

The block diagrams illustrate examples of the division of functional blocks. Accordingly, a plurality of functional blocks may be implemented as a single functional block, a single functional block may be broken up into a plurality of functional blocks, and some of functions may be transferred to another functional block. Moreover, the functions of a plurality of function blocks having similar functions may be processed by a single piece of hardware or software in parallel or by time-division.

Note that the present disclosure also encompasses: embodiments achieved by applying various modifications conceivable to those skilled in the art to the above-described embodiment; and embodiments achieved by optionally combining the elements and the functions of the embodiment without departing from the spirit of the present disclosure.

While an embodiment has been described herein above, it is to be appreciated that various changes in form and detail may be made without departing from the spirit and scope of the present disclosure as presently or hereafter claimed.

### Further Information about Technical Background to this Application

The disclosure of the following patent application including specification, drawings, and claims is incorporated herein by reference in their entirety: Japanese Patent Application No. 2024-170904 filed on Sep. 30, 2024.

### INDUSTRIAL APPLICABILITY

The switch device according to the present disclosure is applicable to operation input devices provided in vehicles.

1. A switch device provided in a vehicle, the switch device comprising:
a panel that receives a user operation;
a cover that displaces between an open position in which the panel is exposed and a closed position in which the panel is covered;
a capacitive sensor electrode provided on an opposite side of the panel relative to a cover side of the panel;
a cover state detector that detects a state of the cover indicating the open position or the closed position; and
a controller that determines, based on an operation signal output by the capacitive sensor electrode, whether an operation has been performed on the switch device, wherein
the controller changes detection sensitivity of the capacitive sensor electrode depending on the state of the cover detected by the cover state detector.

2. The switch device according to claim 1, wherein
the controller sets the detection sensitivity of the capacitive sensor electrode higher when the cover is in the closed position than when the cover is in the open position.

3. The switch device according to claim 1, wherein
the controller switches between (i) a function to be performed in response to receiving an operation performed on the panel when the state of the cover is detected to indicate the open position and (ii) a function to be performed in response to receiving an operation performed on the cover when the state of the cover is detected to indicate the closed position.

4. The switch device according to claim 2, wherein
the controller switches between (i) a function to be performed in response to receiving an operation performed on the panel when the state of the cover is detected to indicate the open position and (ii) a function to be performed in response to receiving an operation performed on the cover when the state of the cover is detected to indicate the closed position.

5. The switch device according to claim 1, wherein
the controller switches to a function corresponding to a particular operation in response to receiving the particular operation performed on the cover when the cover is in the closed position.

6. The switch device according to claim 2, wherein
the controller switches to a function corresponding to a particular operation in response to receiving the particular operation performed on the cover when the cover is in the closed position.

7. The switch device according to claim 1, wherein
the controller sets the detection sensitivity of the capacitive sensor electrode higher when the cover is in the open position than when the cover is in the closed position.

8. The switch device according to claim 1, wherein
when the controller detects that the state of the cover has switched to the open position, the controller sets the detection sensitivity of the capacitive sensor electrode higher for a predetermined time period than the detection sensitivity of the capacitive sensor electrode after a lapse of the predetermined time period.
